(19) United States
(12) Patent Application Publication
(10) Pub. No.: US 2017/0339790 A1
(43) Pub. Date: Nov. 23, 2017

(54) Electronic Component And Method For Producing An Electronic Component Of This Kind

(71) Applicant: Conti Temic microelectronic GmbH, Nurnberg (DE)

(72) Inventors: Frieder Wittmann, Heilsbronn (DE); Karin Beart, Lauf an der Pegnitz (DE); Stefan Müller, Engelthal (DE); Thomas Schmidt, Burglengenfeld (DE); Bernhard Schuch, Neusitz (DE)

(73) Assignee: Conti Temic microelectronic GmbH, Nurnberg (DE)

(21) Appl. No.: 15/674,273

(22) Filed: Aug. 10, 2017

Related U.S. Application Data
(63) Continuation of application No. PCT/EP2016/052093, filed on Feb. 1, 2016.

(30) Foreign Application Priority Data
Feb. 10, 2015 (DE) 10 2015 202 294.3
Jun. 2, 2015 (DE) 10 2015 210 099.5

(51) Int. Cl. H05K 1/18; H05K 3/34; H05K 1/11; H05K 3/32

(52) U.S. Cl. CPC H05K 1/181; H05K 3/321; H05K 3/341; H05K 1/11; H05K 2201/10545; H05K 2203/049; H05K 2201/10227

(57) ABSTRACT

The disclosure relates to an electronic component that includes a printed circuit board with two opposite flat sides and a plurality of electronic components, and a base plate. A number of the electronic components are each fixed on and electrically conductively connected to a rear flat side of the printed circuit board and a further number of the electronic components are each fixed on and electrically conductively connected to a front flat side of the printed circuit board. The base plate has at least one first cutout for receiving electronic components that are arranged on the rear flat side of the printed circuit board. The disclosure also relates to a method for producing an electronic component of this kind.

### CROSS-REFERENCE TO RELATED APPLICATIONS

This application claims the benefit of PCT Application PCT/EP2016/052093, filed Feb. 1, 2012, which claims priority to German Application DE 10 2015 202 294.3, filed Feb. 10, 2015 and German Application DE 10 2015 210 099.5 filed Jun. 2, 2015. The disclosures of the above applications are incorporated herein by reference.

### TECHNICAL FIELD

The disclosure relates to an electronic component and to a method for producing an electronic component of this kind.

### BACKGROUND

Electronic components for integrated mechatronic controllers, in particular control units, which are installed in a transmission or engine compartment of a motor vehicle, have a plurality of electronic component parts. The plurality of electronic component parts are assembled on a printed circuit board to form an integrated circuit. The printed circuit board is usually equipped on one side with electronic component parts.

For the production of the electronic components, for example, a flat side of the printed circuit board is provided with an electrically conductive adhesive. The electrically conductive adhesive may also be referred to as a conductive adhesive, for example, epoxy resin having electrically conductive fillers may be used. Subsequently, all electronic component parts are arranged on the flat side provided with conductive adhesive.

Because of high demands on installation space and ambient temperatures, for example, a temperature up to 150° C., of the electronic components, all electronic component parts designed as semiconductor components are arranged unhoused on the printed circuit board and electrically contacted by means of bond wires in the form of thick wire and/or thin wire bond connections (wire bonding).

In wire bonding, a high level of cleanness of the equipped flat side of the printed circuit board and of the electronic component parts themselves is required to ensure a perfect functionality of the electrical component. This is possible, for example, by means of electrically conductive adhesive bonds, which have a comparatively high electrical resistance and a low thermal conductivity. This may impair a functionality of the circuit arranged on the printed circuit board and therefore of the electronic component.

In addition, it is necessary because of the process, in addition to the semiconductor components, to fix all passive electronic component parts, for example, sensors, capacitors, etc., and special component parts, for example, coils or quartzes, by means of electrically conductive adhesive bonds on the printed circuit board. Passive component parts may typically be soldered, however, this is not possible or at least not advantageous in the case of simultaneous arrangement of semiconductor components having bond wires due to the above-mentioned reasons.

Furthermore, the electronic component parts to be adhesively bonded have certain terminations, which are produced from gold or silver, for example, and are therefore very costly.

In addition, housed semiconductor components cannot be adhesively bonded, because they are typically only available as component parts that can be soldered.

A thermal attachment of the equipped printed circuit board is performed via a planar adhesive bond of the printed circuit board, in particular an unequipped flat side of the printed circuit board, to a base plate or a housing. In this case, all regions of the circuit are attached in a thermally equivalent manner independently of a power loss arising therein.

Therefore, it is desirable to have an electronic component which is improved in relation to the prior art and an improved method for producing an electronic component of this type.

### SUMMARY

One aspect of the disclosure provides an electronic component that includes a printed circuit board having two opposing flat sides and a plurality of electronic component parts, and a base plate. A number of the electronic component parts is fixed and electrically conductively connected to a rear flat side of the printed circuit board and a further number of the electronic component parts is fixed and electrically conductively connected to a front flat side of the printed circuit board. The base plate has at least one first recess for accommodating electronic component parts that are arranged on the rear flat side of the printed circuit board.

The electronic component designed in this manner reduces a component part density on the typically equipped front flat side. Furthermore, an optimum temperature control of the electronic component parts as a function of a power loss is thus possible. The recess in the base plate corresponds in this case to a cavity for accommodating the electronic component parts, which are arranged on the rear flat side of the printed circuit board.

Implementations of the disclosure may include one or more of the following optional features. In some implementations, the electronic component enables a combination of various connection technologies. For example, the number of the electronic component parts is fixed in an integrally joined manner on the rear flat side by solder points and electrically conductively connected to the printed circuit board. The further number of the electronic component parts is adhesively bonded to the front flat side by means of an electrically conductive adhesive and electrically conductively connected to the printed circuit board by means of wire contacting.

Alternatively, in some examples, the number of the electronic component parts can also be fixed in an integrally joined manner on the front flat side by solder points and electrically conductively connected to the printed circuit board. The further number of the electronic component parts is then adhesively fixed on the rear flat side and electrically conductively connected to the printed circuit board by means of wire contacting.

It is therefore possible, in spite of the use of an electrically conductive adhesive, to solder further electronic component parts in the circuit. This advantageously enables the integration of low-power-loss, housed semiconductor components in the circuit by means of soldering.

In some implementations, a position of one of the electronic component parts on one of the flat sides of the printed circuit board is dependent on a position of an electronic component part on the opposing flat side of the printed circuit board having a certain power loss. A dissipation of higher levels of waste heat is thus ensured in the case of electronic component parts having high power loss. The temperature control of such electronic component parts is therefore optimized.

In some examples, that the printed circuit board and the base plate are bonded to one another in an integrally joined manner a thermally conductive adhesive. Alternatively, in some examples, the printed circuit board and the base plate are soldered to one another.

In some implementations, the wire contacting includes at least one thick bond wire, for example, made of aluminum. Alternatively or additionally, the wire contacting includes at least one thin bond wire, for example, made of gold.

Another aspect of the disclosure provides a method for producing the described electronic component. The method includes providing an unequipped printed circuit board. The printed circuit board has two opposing flat sides being a rear flat side and a front flat side. The method includes providing a plurality of electronic component parts, and equipping the printed circuit board with the plurality of electronic component parts. A number of the electronic component parts from the plurality of electronic component parts is arranged on the rear flat side, fixed in an integrally joined manner, and electrically conductively connected to the printed circuit board. Subsequently a further number of the electronic component parts from the plurality of electronic component parts is arranged on the front flat side, fixed in an integrally joined manner, and electrically conductively connected to the printed circuit board. The method also includes integrally joined bonding of the printed circuit board equipped on both sides to a base plate. The base plate is provided with at least one first recess for accommodating electronic component parts that are arranged on the rear flat side of the printed circuit board.

As described in the method, a printed circuit board equipped on both sides is producible, where a greater number of electronic component parts may be soldered in relation to the prior art. A soldered bond has a substantially lower thermal resistance in this case than an adhesive bond, so that a functionality of the electronic component is improved.

In some examples, the number of electronic component parts is soldered to the rear flat side, and the further number of electronic component parts is adhesively bonded to the front flat side and is electrically conductively connected to the printed circuit board by means of wire contacting.

In the method, various connection technologies may therefore be combined with one another for the two-sided equipping of the printed circuit board.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 schematically shows a sectional illustration of an implementation according to the disclosure of an electronic component having a printed circuit board equipped on both sides.

FIG. 2 schematically shows a sectional illustration of an alternative implementation according to the disclosure of an electronic component having a printed circuit board equipped on both sides.

FIG. 3 shows a method flow chart of a method for producing an electronic component.

Parts corresponding to one another are provided with the same reference signs in all figures.

### DETAILED DESCRIPTION

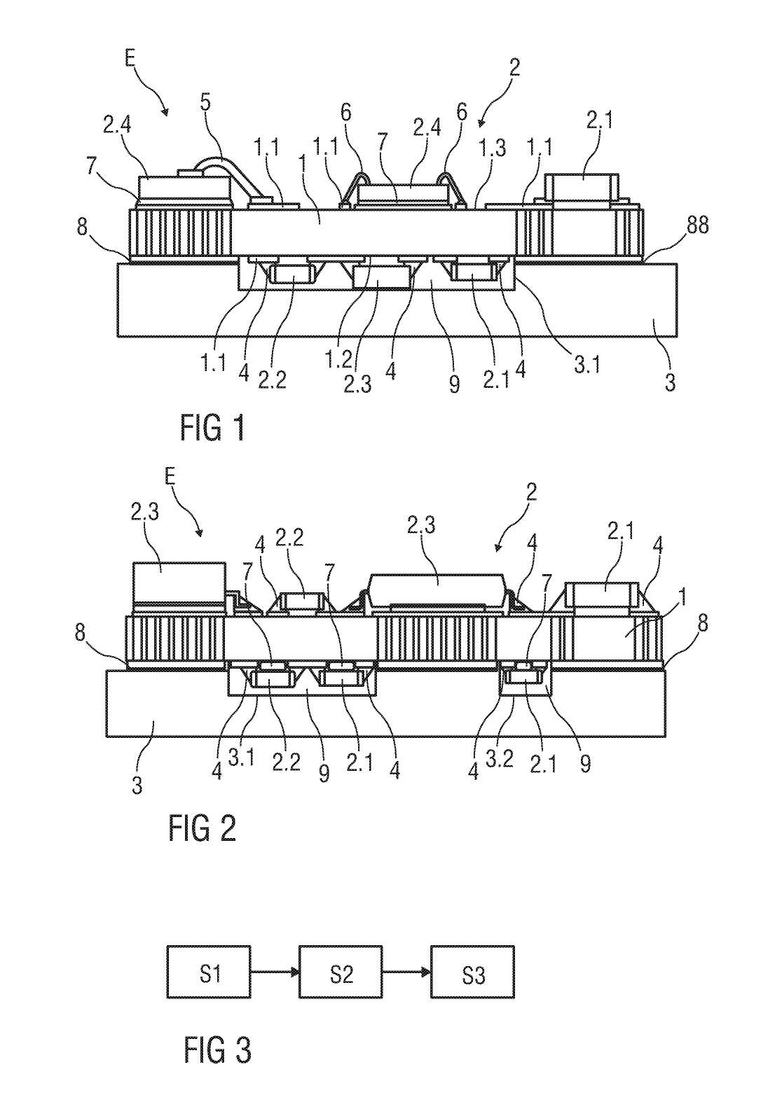

FIG. 1 shows a sectional illustration, in particular a cross section, of an electronic component E. The electronic component E may be arranged in a control unit for motor vehicles, for example, in a transmission control unit, where not all components of the electronic component E are shown.

The electronic component E includes a printed circuit board 1 having a plurality of electronic component parts 2 and a base plate 3. The base plate 3 is bonded in an integrally joined manner to the printed circuit board 1.

The printed circuit board 1 represents a substrate or circuit carrier and is used for the mechanical fastening of the electronic component parts 2 as well as their electrical connection. For example, the printed circuit board 1 is formed from electrically insulating, fiber-reinforced plastic and has a number of electrically conductive conductor tracks 1.1.

Furthermore, the printed circuit board 1 has two flat sides 1.2, 1.3, where a rear flat side 1.2 is a side facing the base plate 3 and a front flat side 1.3 is a side of the printed circuit board 1 facing away from the base plate 3.

According to the disclosure, the printed circuit board 1 has electronic component parts 2 both on the front flat side 1.3 and also on the rear flat side 1.2. In other words, the printed circuit board 1 is equipped on both sides.

In some implementations, an electrical resistor 2.1, an electrical capacitor 2.2, and a housed semiconductor component 2.3, for example, a housed diode or bipolar transistor, are arranged as electronic component parts 2 on the rear flat side 1.2 and are each mechanically fixed on the rear flat side 1.2 and electrically conductively connected to the conductor tracks 1.1 by means of solder points 4.

Because the rear flat side 1.2 is the flat side of the printed circuit board 1 facing toward the base plate 3, the base plate 3 has a first recess 3.1 for accommodating the electrical resistor 2.1, the electrical capacitor 2.2, and the housed semiconductor component 2.3. The first recess 3.1 is provided with a filler material 9, for example, a thermally conductive paste or a potting compound.

A thermally conductive adhesive 8 is arranged between unequipped sections of the rear flat side 1.2 of the printed circuit board 1 and the base plate 3 for the integrally joined bonding of the printed circuit board 1 and the base plate 3. The printed circuit board 1 is therefore additionally thermally connected to the base plate 3. Alternatively, a solder point 4 can also be arranged instead of the thermally conductive adhesive 8. The base plate 3 is formed from metal, for example. Alternatively, the base plate 3 can also be formed as a plastic-metal hybrid.

In some implementations, as shown, two unhoused semiconductor components 2.4 and a further electrical resistor 2.1 are arranged as electronic component parts 2 on the front flat side 1.3.

An unhoused semiconductor component 2.4, which is arranged on the left in the observation direction, is electrically conductively connected by a thick bond wire 5, for example, an aluminum bond wire, to the conductor tracks 1.1 and is fixed in an integrally joined manner on the front flat side 1.3 by an electrically conductive adhesive 7.

An unhoused semiconductor component 2.4, which is arranged on the right in the observation direction, is electrically conductively connected by two thin bond wires 6, for example, two gold bond wires, to the conductor tracks 1.1 and is fixed in an integrally joined manner on the front flat side 1.3 by the electrically conductive adhesive 7.

The further electrical resistor 2.1 is both electrically conductively connected to the conductor tracks 1.1 and also fixed in an integrally joined manner on the front flat side 1.3 by the electrically conductive adhesive 7.

FIG. 2 shows an electronic component E in a sectional illustration, in particular in a cross section.

The electronic component E includes, similarly to the previous electronic component E described in FIG. 1, a printed circuit board 1 having a plurality of electronic component parts 2 and a base plate 3, which is bonded in an integrally joined manner to the printed circuit board 1.

Furthermore, as previously described with respect to FIG. 1, the printed circuit board 1 has a rear flat side 1.2 and a front flat side 1.3. In some implementations, two electrical resistors 2.1 and an electrical capacitor 2.2 are arranged on the rear flat side 1.2 as electronic component parts 2 and are each electrically conductively connected to conductor tracks 1.1 and are fixed in an integrally joined manner on the rear flat side 1.2 by solder points 4 and an electrically conductive adhesive 7.

The base plate 3 has two recesses 3.1, 3.2 in this case, where a first recess 3.1 accommodates the electrical capacitor 2.2 and one of the electrical resistors 2.1. A second recess 3.2 accommodates the other electrical resistor 2.1.

A thermally conductive adhesive 8 for the integrally joined bonding of the printed circuit board 1 to the base plate 3 is also arranged between unequipped sections of the rear flat side 1.2 and the base plate 3 in this case. The printed circuit board 1 is therefore additionally thermally connected to the base plate 3. Alternatively, a solder point 4 can also be provided instead of the thermally conductive adhesive 8.

As shown, two housed semiconductor components 2.3, for example, a housed field-effect transistor and a housed integrated circuit, an electrical capacitor 2.2, and an electrical resistor 2.1 are arranged on the front flat side 1.3 as electronic component parts 2.

The electronic component parts 2 arranged on the front flat side 1.3 are each bonded in an integrally joined manner and electrically conductively connected by means of solder points 4 to the front flat side 1.3.

FIG. 3 shows a method flow chart of a method according to the disclosure for producing the electronic component E.

The method is described in greater detail hereafter based on the electronic component E shown in FIG. 1.

In a first method step S1, the rear flat side 1.2 of the printed circuit board 1 is equipped with electronic component parts 2, the power loss of which is low in relation to other electronic component parts 2, because these electronic component parts 2 cannot be directly thermally connected to the base plate 3 and a heat loss arising in this case cannot be efficiently dissipated.

In some examples, a soldering process is carried out for the fixing and electrical contacting of the electronic component parts 2. Alternatively, the electronic component parts 2 can also be adhesively bonded and electrically conductively connected by means of a conductive adhesive to the rear flat side 1.2. Wire contacting (wire bonding) is not possible on the rear flat side 1.2, because a required cleanness of the surfaces cannot be ensured due to the soldering processes.

The position of the electronic component parts 2 on the rear flat side 1.2 is selected depending on a future position of electronic component parts 2 on the front flat side 1.3 which have high power loss and therefore generate a high level of waste heat in relation to the other electronic component parts 2.

In a second method step S2, the electrically conductive adhesive 7 is applied, for example, by means of screen printing, to the front flat side 1.3 of the printed circuit board 1. Subsequently thereto, all electronic component parts 2, which are provided for wire contacting and have high power loss, are adhesively bonded to the front flat side 1.3.

In this case, one of the unhoused semiconductor components 2.4 is electrically conductively connected to the conductor tracks 1.1 by means of the thick bond wire 5 after the curing of the electrically conductive adhesive 7.

The other of the unhoused semiconductor components 2.4 is electrically conductively connected to the conductor tracks 1.1 by means of the thin bond wires 6 after the curing of the electrically conductive adhesive 7.

The second electrical resistor 2.1 is exclusively electrically conductively connected to the conductor tracks 1.1 and also fixed in an integrally joined manner on the front flat side 1.3 by means of the electrically conductive adhesive 7, as already described in FIG. 1.

A contamination on the front flat side 1.3 may be minimized by the use of the electrically conductive adhesive 7 on the front flat side 1.3, so that an optimum contact surface for wire contacting is ensured.

In a third method step S3, the printed circuit board 1 equipped on both sides is bonded in an integrally joined manner to the base plate 3, for example, by the thermally conductive adhesive 8 or alternatively by a further soldering process.

The base plate 3 has the recess 3.1 for accommodating the electronic component parts 2 on the rear flat side 1.2, as already described. A total height of the electronic component E thus remains equal, so that no additional installation space requirement results.

The recess 3.1 can optionally be filled using the filler material 9. The filling is performed either before the integrally joined bonding of the base plate 3 to the printed circuit board 1 or by channels introduced into the base plate 3 (not shown here).

A thermal connection of the entire circuit assembled on the printed circuit board 1 is increased in relation to the prior art by the filler material 9. The above-mentioned channels in the base plate 3 and/or channels in the printed circuit board 1 enable air bubbles to be avoided or at least reduced.

The described solution according to the disclosure enables a combination of different connection technologies with the option of spatially separated processes, i.e., for example, soldering processes on the rear flat side 1.2 and adhesive bonding and wire contacting on the front flat side 1.3. In addition, a temperature control of the circuit on the printed circuit board 1 is possible as a function of a power loss of individual electronic component parts 2. In other words: the solution according to the disclosure enables partial heating of the circuit on the printed circuit board 1 in thermally relevant regions.

Furthermore, the solution according to the disclosure enables a reduction of a component part density on a flat side of the printed circuit board 1 due to the two-sided equipping of the printed circuit board 1.

Furthermore, in spite of the use of the electrically conductive adhesive 7, electronic component parts 2 may be soldered. It is therefore also possible to integrate low-power-loss, housed semiconductor components 2.3 in the circuit by soldering. Mechanically and chemically sensitive thin bond wires 6 and thick bond wires are protected, because they are first applied after the soldering process. Therefore, chip resistors and chip capacitors and also special component parts may be used, which have a more cost-effective termination than the prior art. For example, terminations made of cost-effective tin can be used, wherein the component parts that have such terminations have a high availability.

A number of implementations have been described. Nevertheless, it will be understood that various modifications may be made without departing from the spirit and scope of the disclosure. Accordingly, other implementations are within the scope of the following claims.

What is claimed is:

1. An electronic component comprising:
a printed circuit board including:
two opposing flat sides being a rear flat side and a front flat side, and
a plurality of electronic component parts, wherein a number of the electronic component parts is fixed and electrically conductively connected to the rear flat side of the printed circuit board and a further number of the electronic component parts is fixed and electrically conductively connected to the front flat side of the printed circuit board; and
a base plate having at least one first recess for accommodating electronic component parts, which are arranged on the rear flat side of the printed circuit board.

2. The electronic component of claim 1, wherein the number of the electronic component parts is fixed in an integrally joined manner on the rear flat side by solder points and electrically conductively connected to the printed circuit board.

3. The electronic component of claim 1, wherein the further number of the electronic component parts is adhesively bonded to the front flat side by means of an electrically conductive adhesive and electrically conductively connected to the printed circuit board by wire contacting.

4. The electronic component of claim 1, wherein a position of one of the electronic component parts on one of the flat sides of the printed circuit board is dependent on a position of an electronic component part on the opposing flat side of the printed circuit board having a certain power loss.

5. The electronic component of claim 1, wherein the printed circuit board and the base plate are bonded to one another in an integrally joined manner by means of a thermally conductive adhesive.

6. The electronic component of claim 3, wherein the wire contacting comprises at least one thick bond wire.

7. The electronic component of claim 3, wherein the wire contacting comprises at least one thin bond wire.

8. A method for producing an electronic component, the method comprising:
providing an unequipped printed circuit board, the printed circuit board having two opposing flat sides being a rear flat side and a front flat side;
providing a plurality of electronic component parts;
equipping the printed circuit board with the plurality of electronic component parts, wherein:
a number of the electronic component parts from the plurality of electronic component parts is arranged on the rear flat side, fixed in an integrally joined manner, and electrically conductively connected to the printed circuit board, and
subsequently a further number of the electronic component parts from the plurality of electronic component parts is arranged on the front flat side, fixed in an integrally joined manner, and electrically conductively connected to the printed circuit board; and
integrally joined bonding of the printed circuit board equipped on both sides to a base plate, wherein the base plate is provided with at least one first recess for accommodating electronic component parts that are arranged on the rear flat side of the printed circuit board.

9. The method of claim 8, wherein the number of electronic component parts is soldered to the rear flat side and the further number of electronic component parts is adhesively bonded to the front flat side and is electrically conductively connected to the printed circuit board by wire contacting.
